(19) United States
(12) Patent Application Publication
(10) Pub. No.: US 2025/0233513 A1
(43) Pub. Date: Jul. 17, 2025

(54) POWER CONVERSION DEVICE

(71) Applicant: Hyundai Transys Inc., Seosan-si (KR)

(72) Inventors: Il Hoon HWANG, Hwaseong-si (KR); Dae Kyun KIM, Hwaseong-si (KR)

(21) Appl. No.: 19/014,333

(22) Filed: Jan. 9, 2025

(30) Foreign Application Priority Data
Jan. 12, 2024 (KR) 10-2024-0005428

(51) Int. Cl. H02M 1/32; H02M 7/00; H02M 7/537

(52) U.S. Cl. CPC H02M 1/327; H02M 7/003; H02M 7/537

(57) ABSTRACT

Provided is a power conversion device including a power element, a casing in which the power element is disposed, a cooling flow path provided in the casing to allow cooling fluid to flow therethrough to cool the casing and having a plurality of contact enhancement portions to increase a contact area between the casing and the cooling fluid, and a heat exchanger provided between the power element and the casing to exchange heat between the casing and the power element.

### CROSS-REFERENCE TO RELATED APPLICATION

This application claims the benefit of Korean Patent Application No. 10-2024-0005428, filed Jan. 12, 2024, the disclosure of which is incorporated by reference herein in its entirety.

### BACKGROUND

### Field

Embodiments of the present disclosure relate to a power conversion device and, more particularly, to a power conversion device having improved cooling and heat dissipation performance.

### Discussion of the Background

In general, a power conversion device receives DC current from a high-voltage battery, converts the DC current to AC current, and supplies the AC current to a motor while adjusting the magnitude and phase of the AC current to control the torque and rotational speed of the motor.

The power conversion device requires a cooling system because when the temperature rises to or above a predetermined level due to the heat generated by power elements (e.g., insulated gate bipolar transistor (IGBT), metal oxide semiconductor field effect transistor (MOSFET), and the like) that convert DC current from a high-voltage battery to AC current, the performance of the power conversion device may be degraded or the power conversion device may be damaged.

However, since the cooling device needs to be fitted to a casing in which the power elements are mounted with a cooling pipe through which coolant flows in or out, the fitting operation may be cumbersome. In addition, the cooling device has a circular cross-section, which does not have a large cooling effect on the power elements, resulting in poor heat dissipation performance of the power elements. Therefore, there is a need to improve this problem.

The background technology of the present disclosure is disclosed in Korean Patent No. 10-1922991 (registered on Nov. 22, 2018 and entitled “Power Element Cooling Device for Power Conversion Device”).

### SUMMARY

Various embodiments are directed to a power conversion device having improved cooling and heat dissipation performance.

In an embodiment of the present disclosure, a power conversion device includes: a power element; a casing in which the power element is disposed; a cooling flow path provided in the casing to allow cooling fluid to flow therethrough to cool the casing and having a plurality of contact enhancement portions to increase a contact area between the casing and the cooling fluid; and a heat exchanger provided between the power element and the casing to exchange heat between the casing and the power element.

The power conversion device may further include vortex generators provided in the casing, connected to the cooling flow path, and configured to generate a vortex of cooling fluid that flows through the cooling flow path.

The vortex generators may be provided as ring-shaped recesses on the casing and spaced apart from each other in a longitudinal direction of the cooling flow path.

The cooling flow path may include: a main body allowing the cooling fluid to flow therethrough and provided in contact with the casing; and the plurality of contact enhancement portions protruding from an outer surface of the main body so as to be circumferentially spaced apart from each other, allowing the cooling fluid to flow therethrough, and in contact with the casing.

The vortex generators may be connected to the main body of the cooling flow path and the contact enhancement portions.

The casing may include: a casing body in contact with the heat exchanger and a first contact surface of each of the contact enhancement portions, and including the vortex generators provided on an inner surface thereof; and a plurality of casing extensions protruding from the inner surface of the casing body to be circumferentially spaced apart from each other, disposed between the plurality of the contact enhancement portions, and in contact with the main body of the cooling flow path and with second and third contact surfaces of the contact enhancement portions.

The casing body and the casing extensions may be cooled by cooling fluid flowing through at least one of the main body of the cooling flow path and the contact enhancement portions.

The power conversion device according to the present disclosure is provided on the cooling flow path with the contact enhancement portions to increase the contact area between the casing and the cooling fluid to improve the cooling performance of the cooling flow path, thereby increasing the cooling performance of the power element during heat exchange between the casing and the power element through the heat exchanger. Accordingly, the heat dissipation performance of the power element may be improved.

In addition, since the cooling flow path is integrally formed in the casing, it is not necessary to fit a separate cooling device to the casing. Accordingly, the reduced number of parts may reduce the costs of parts, and the assembly process may be simplified and the assembly time may be reduced.

### BRIEF DESCRIPTION OF THE DRAWINGS

FIG. 1 is a schematic view illustrating a power conversion device according to an embodiment of the present disclosure;

FIG. 2 is a cross-sectional view taken along line A-A′ of FIG. 1;

FIG. 3 is an enlarged view of the major part of FIG. 2;

FIG. 4 is a side view illustrating a power conversion device according to an embodiment of the present disclosure;

FIG. 5 is a view illustrating a power conversion device according to an embodiment of the present disclosure in which cooling fluid flows through a cooling flow path thereof; and

FIG. 6 is a view of FIG. 5 viewed from a different direction.

### DETAILED DESCRIPTION

Hereinafter, a power conversion device will be described below with reference to the accompanying drawings through various exemplary embodiments.

In the specification and drawings, thicknesses of lines in the drawings and sizes of constituent elements may be exaggerated for clarity and convenience. Further, the following terms will be defined, considering functions thereof in the present disclosure, and may be varied according to intentions and customs of a user or an operator. Therefore, the terms should be defined on the basis of the contents of the entire specification.

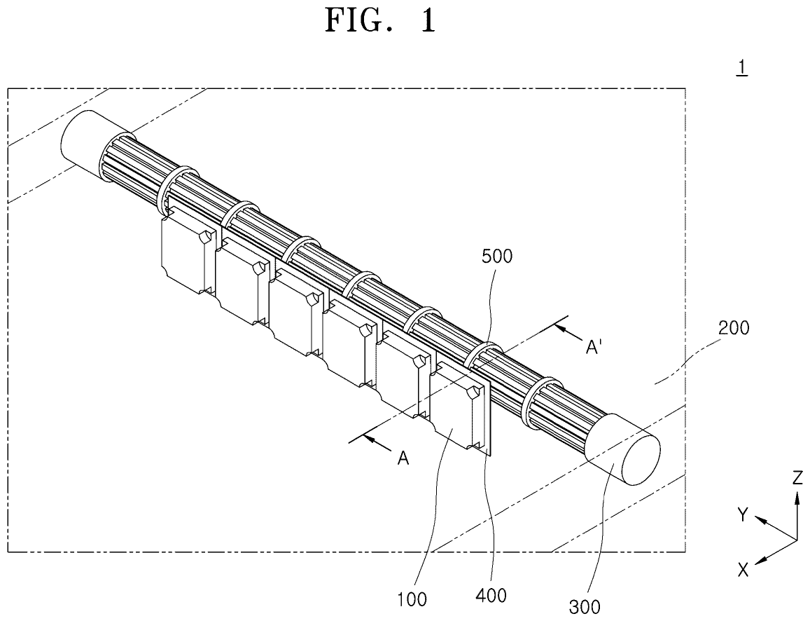

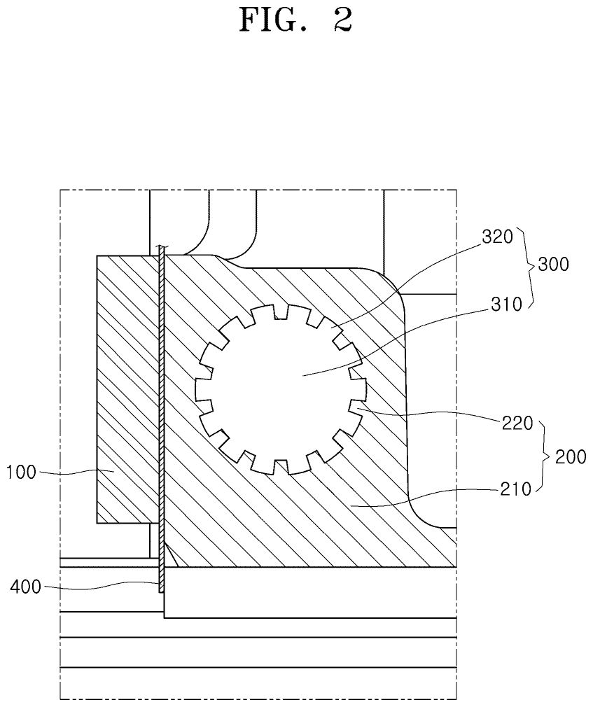

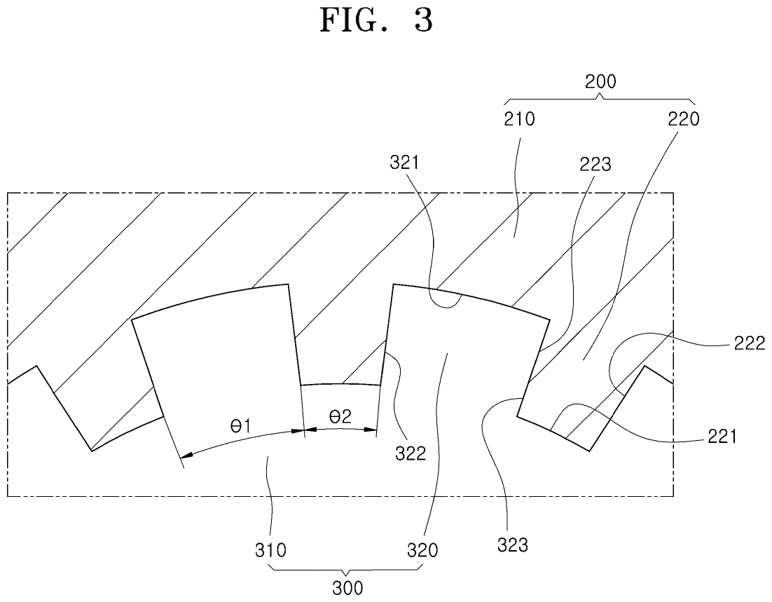

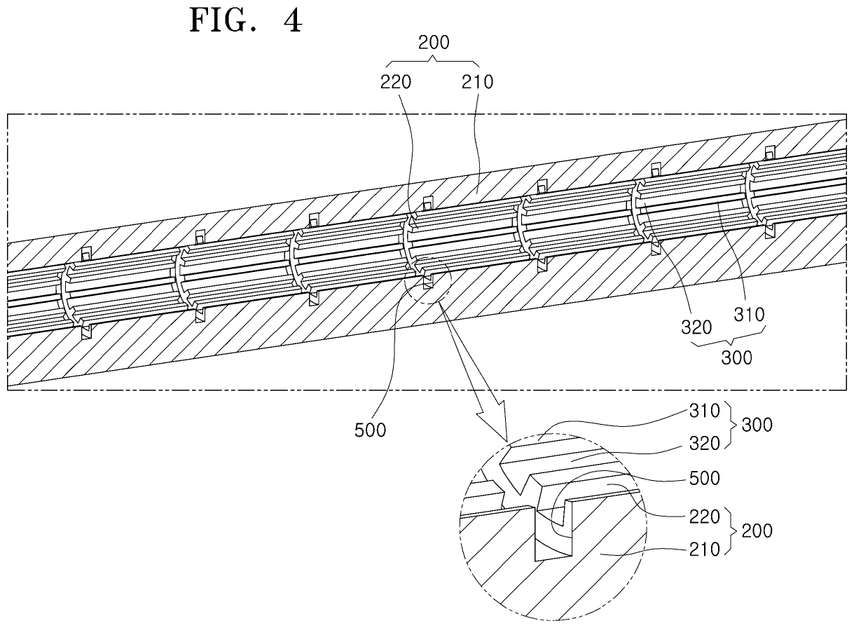

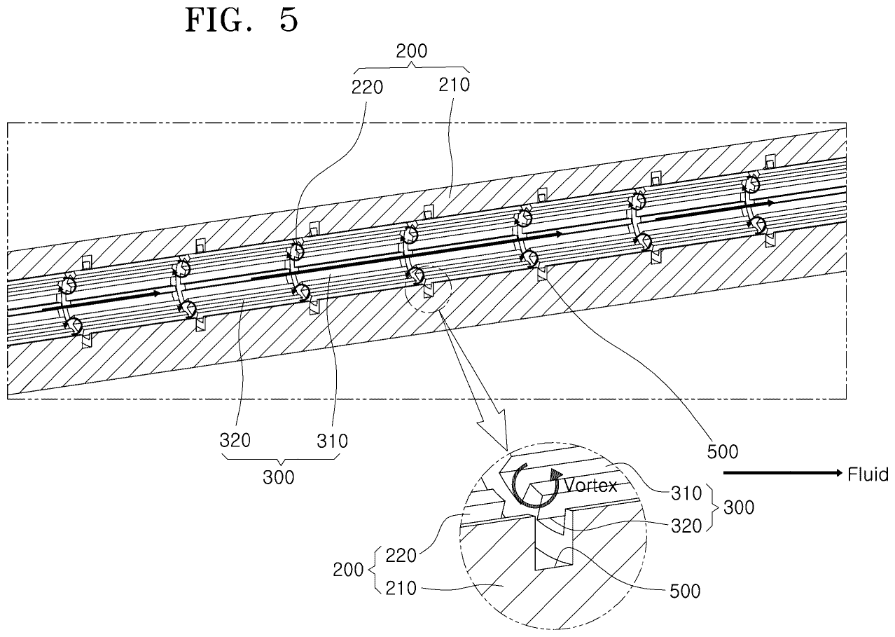

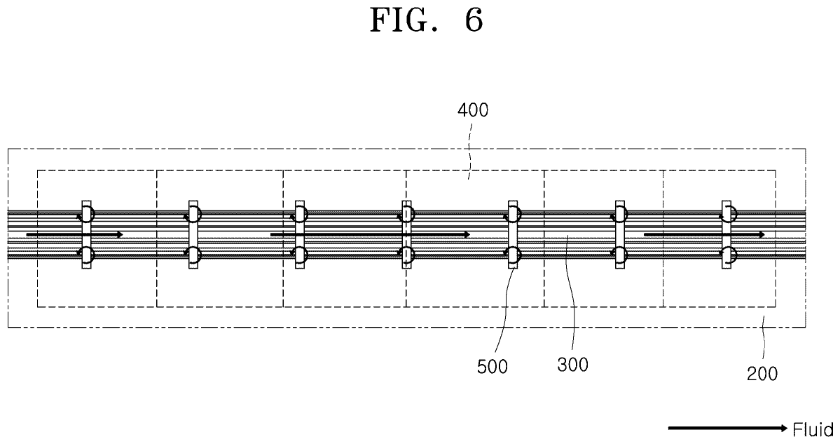

FIG. 1 is a schematic view illustrating a power conversion device according to an embodiment of the present disclosure, FIG. 2 is a cross-sectional view taken along line A-A′ of FIG. 1, FIG. 3 is an enlarged view of the major part of FIG. 2, FIG. 4 is a side view illustrating a power conversion device according to an embodiment of the present disclosure, FIG. 5 is a view illustrating a power conversion device according to an embodiment of the present disclosure in which cooling fluid flows through a cooling flow path thereof, and FIG. 6 is a view of FIG. 5 viewed from a different direction.

Referring now to FIGS. 1 to 6, the power conversion device 1 according to the embodiment of the present disclosure includes a power element 100, a casing 200, a cooling flow path 300, and a heat exchanger 400.

The power conversion device may include a plurality of power elements 100, which are disposed in the casing 200 so as to be spaced apart from each other along the cooling flow path 300. The power elements 100 may include insulated gate bipolar transistors (IGBTs), metal oxide semiconductor field effect transistors (MOSFETs), or the like, and may be in contact with a plurality of heat exchangers 400, respectively.

The power elements 100 are disposed in the casing 200. The casing 200 has a cooling flow path 300 formed therein. Here, the cooling flow path 300 extends in a Y-axis direction in the casing 200, and the power elements 100 are disposed in the casing 200 such that the power elements are spaced apart from each other along the cooling flow path 300.

The casing 200 may include a casing body 210 and casing extensions 220. The casing body 210 abuts the heat exchanger 400 and a first contact surface 321 of a contact enhancement portion 320, and has on an inner surface thereof a plurality of vortex generators 500 to be described later.

The plurality of vortex generators 500 are provided longitudinally on the inner surface of the casing body 210 so as to be spaced apart from each other. Here, the vortex generators 500 may be formed as ring-shaped recesses.

The casing extensions 220 protrude from the inner surface of the casing body 210 so as to be circumferentially spaced apart from each other so that the casing extensions are arranged between the plurality of contact enhancement portions 320 in such a manner as to be in contact with a main body 310 of the cooling flow path and opposite lateral contact surfaces 322 and 323, i.e., second and third contact surfaces, of the contact enhancement portions 320.

The casing extension 220 may have a first casing extension surface 221, a second casing extension surface 222, and a third casing extension surface 223. The first casing extension surface 221 may be in contact with the main body 310 of the cooling flow path 300. Accordingly, the first casing extension surface 221 may be cooled by cooling fluid flowing through the main body 310 of the cooling flow path.

The second casing extension surface 222 may be in contact with the second contact surface 322 of the contact enhancement portion 320, and the third casing extension surface 223 may be in contact with the third contact surface 323 of the contact enhancement portion 320. Accordingly, the second casing extension surface 222 and the third casing extension surface 223 may be cooled by cooling fluid flowing through the contact enhancement portion 320.

The casing body 210 and the casing extensions 220 may be cooled by cooling fluid flowing through at least one of the main body 310 of the cooling flow path and the contact enhancement portions 320. In other words, the casing 200 may be directly cooled by the cooling fluid flowing through the cooling flow path 300, which may improve cooling efficiency.

The cooling flow path 300 is provided inside the casing 200 to allow cooling fluid to flow therethrough to cool the casing 200, and has the contact enhancement portions 320 to increase a contact area between the casing 200 and the cooling fluid.

The cooling flow path 300 is disposed in the Y-axis direction in the casing 200, such that the cooling fluid flow therethrough. Cooling fluid may be introduced into one of both ends of the cooling flow path, may flow through the interior of the cooling flow path 300, and may be discharged out of the other end of the cooling flow path 300.

As such, since the cooling flow path 300 is integrally formed in the casing 200, it is not necessary to fit a separate cooling device to the casing 200. Accordingly, the reduced number of parts may reduce the costs of parts, and the assembly process may be simplified and the assembly time may be reduced.

Furthermore, since the cooling flow path 300 is provided with the contact enhancement portions 320 that increase the contact area between the casing 200 and the cooling fluid, the cooling performance of the cooling flow path 300 may be improved to increase the cooling performance of the power element 100 during heat exchange between the casing 200 and the power element 100 through the heat exchanger 400. Accordingly, the heat dissipation performance of the power element 100 may be improved.

The cooling flow path 300 may have a spline shape in cross-section and may include a main body 310 and a plurality of contact enhancement portions 320 (see FIGS. 2 and 3). The main body 310 of the cooling flow path is in contact with the casing 200, and the cooling fluid flows therethrough.

The main body 310 of the cooling flow path is formed in the casing 200 and has a cylindrical shape. The main body 310 of the cooling flow path is disposed in the Y-axis direction in the casing 200. The cooling fluid flowing through the main body 310 of the cooling flow path is in contact with the casing 200.

The main body 310 of the cooling flow path may be in contact with the plurality of casing extensions 220 provided on the casing 200. In other words, the cooling fluid flowing through the main body 310 of the cooling flow path may be in contact with the first casing extension surfaces 221 of the casing extensions 220.

The plurality of contact enhancement portions 320 protrude from an outer surface of the main body 310 of the cooling flow path so as to be circumferentially spaced apart from each other so that the contact enhancement portions are in contact with the casing 200, and the cooling fluid flows around the contact enhancement portions. The contact enhancement portions 320 may be in contact with the casing body 210 and the plurality of casing extensions 220 of the casing 200. In other words, cooling fluid flowing through respective contact enhancement portions 320 may be in contact with the casing body 210 and the plurality of casing extensions 220. The contact enhancement portions 320 may be in contact with the casing body 210, and the second casing extension surfaces 222 and the third casing extension surfaces 223 of the casing extensions 220.

As a result, since the cooling flow path 300 has a larger contact area with the casing 200 than the conventional cooling flow path having a simply circular cross-section, the cooling performance of the cooling flow path 300 may be improved.

Furthermore, since the cooling flow path 300 has a spline-shaped cross-section such that the flow rate of the cooling fluid is slowed down through the plurality of contact enhancement portions 320 to improve the cooling efficiency, the cooling performance of the power elements 100 may be increased during heat exchange between the casing 200 and the power elements 100 through heat exchangers of the heat exchanger 400, thereby increasing the heat dissipation performance of the power elements 100.

For example, the contact area between the casing and the conventional cooling flow path having a circular cross-section with a radius of 6.5 mm and a length of 150 mm may be calculated as 6126.11 mm². Specifically, the formula for obtaining the contact area between the cooling flow path and the casing may be 6.5×2×3.14×150, which is calculated as 6126.11 mm².

On the other hand, the contact area between the casing 200 and the present cooling flow path 300 having a spline shape with a radius of 6.5 mm and a length of 150 mm may be calculated as 9943.761 mm².

That is, since the outer ring spline area is 3640.857 mm² and the inner ring spline area is 2102.904 mm², the spline tooth surface may have an area of 4200 mm². Based on this, the contact area between the cooling flow path 300 and the casing 200 is calculated as 9943.761 mm².

Specifically, the formula for obtaining the outer ring spline area is 2×6.5×3.14×(15.282/360)×14×150, which is calculated as 3640.857 mm². Here, 15.282 may be the outer ring spline angle θ1 of the contact enhancement portion 320, and 14 may be the number of contact enhancement portions 320 (see FIGS. 2 and 3).

The formula for obtaining the inner ring spline area may be 2×5.5×3.14×(10.431/360)×14×150, which is calculated as 2102.904 mm². Here, 10.431 may be the inner ring spline angle θ2 of the casing extension 220, and 14 may be the number of casing extensions 220 (see FIGS. 2 and 3).

The formula for obtaining the area of the spline tooth surface may be 1×14×2×150, which is calculated as 4200 mm². Here, 1 is the length of each of the second casing extension surface 222 and the third casing extension surface 223 of the casing extension 220 that is 1 mm, and 2 may be the number of the second casing extension surfaces 222 and the third casing extension surfaces 223.

The contact area between the cooling flow path 300 and the casing 200 according to the present disclosure is 9943.761 mm², which may be larger than the contact area of the conventional cooling flow path having a circular cross-section and the casing according to the related art, which is 6126.11 mm².

As such, the cooling flow path 300 according to the present disclosure has a larger contact area with the casing 200 compared to the conventional cooling flow path, thereby improving the cooling efficiency of the cooling flow path 300.

Accordingly, during heat exchange between the casing 200 and the power element 100 through the heat exchanger 400, the cooling performance of the power element 100 may be increased, thereby improving the heat dissipation performance of the power element 100.

The heat exchanger 400 is provided between the power element 100 and the casing 200 to exchange heat between the casing 200 and the power element 100. As the heat exchanger 400 transfers heat generated by the power element 100 to the casing 200, the cooling flow path 300 provided in the casing 200 may cool the heat transferred to the casing 200.

As the heat transferred to the casing 200 is cooled, heat exchange occurs between the casing 200 and the power element 100 through the heat exchanger 400, thereby cooling the power element 100.

The power conversion device 1 may further include a plurality of vortex generators 500. The vortex generator 500 is formed in the casing 200 so as to be connected to the cooling flow path 300 such that a vortex of cooling fluid is generated while flowing through the cooling flow path 300. The vortex generators 500 are connected to the main body 310 of the cooling flow path and the contact enhancement portions 320 of the cooling flow path 300.

The vortex generators 500 are formed on the casing 200 as ring-shaped recesses that are spaced apart from each other in the longitudinal direction of the cooling flow path 300. The vortex generators 500 may be spaced apart from each other in the Y-axis direction on the casing 200.

As such, as the cooling fluid flows through the vortex generators 500 while passing through the cooling flow path 300, a vortex of cooling fluid is generated so that the cooling effect of the cooling flow path 300 may be further improved.

As a result, during heat exchange between the casing 200 and the power element 100 through the heat exchanger 400, the cooling performance of the power element 100 may be further enhanced, which may further improve the heat dissipation performance of the power element 100.

Although exemplary embodiments of the present disclosure have been disclosed for illustrative purposes, a person having ordinary skill in the art will appreciate that various modifications, additions and substitutions are possible, without departing from the scope and spirit of the present disclosure as defined in the accompanying claims. Thus, the true technical scope of the present disclosure should be defined by the following claims.

What is claimed is:

1. A power conversion device comprising:
a power element;
a casing in which the power element is disposed;
a cooling flow path provided in the casing to allow cooling fluid to flow therethrough to cool the casing and having a plurality of contact enhancement portions to increase a contact area between the casing and the cooling fluid; and
a heat exchanger provided between the power element and the casing to exchange heat between the casing and the power element.

2. The power conversion device of claim 1, further comprising vortex generators provided in the casing, connected to the cooling flow path, and configured to generate a vortex of cooling fluid that flows through the cooling flow path.

3. The power conversion device of claim 2, wherein the vortex generators are provided as ring-shaped recesses on the casing and spaced apart from each other in a longitudinal direction of the cooling flow path.

4. The power conversion device of claim 3, wherein the cooling flow path comprises:
a main body allowing the cooling fluid to flow therethrough and provided in contact with the casing; and
the plurality of contact enhancement portions protruding from an outer surface of the main body so as to be circumferentially spaced apart from each other, allowing the cooling fluid to flow therethrough, and in contact with the casing.

5. The power conversion device of claim 4, wherein the vortex generators are connected to the main body of the cooling flow path and the contact enhancement portions.

6. The power conversion device of claim 5, wherein the casing comprises:
a casing body in contact with the heat exchanger and a first contact surface of each of the contact enhancement portions, and comprising the vortex generators provided on an inner surface thereof; and
a plurality of casing extensions protruding from the inner surface of the casing body to be circumferentially spaced apart from each other, disposed between the plurality of the contact enhancement portions, and in contact with the main body of the cooling flow path and with second and third contact surfaces of the contact enhancement portions.

7. The power conversion device of claim 6, wherein the casing body and the casing extensions are cooled by cooling fluid flowing through at least one of the main body of the cooling flow path and the contact enhancement portions.
